(19) United States
(12) Patent Application Publication
(10) Pub. No.: US 2014/0234780 A1
(43) Pub. Date: Aug. 21, 2014

(54) LITHOGRAPHY WITH REDUCED FEATURE PITCH USING ROTATING MASK TECHNIQUES

(71) Applicant: Rolith, Inc., Pleasanton, CA (US)

(72) Inventors: Boris Kobrin, Pleasanton, CA (US); Mark Brongersma, Redwood City, CA (US); Edward Barnard, Redwood City, CA (US)

(73) Assignee: ROLITH, INC., PLEASANTON, CA (US)

(21) Appl. No.: 14/261,345

(22) Filed: Apr. 24, 2014

Related U.S. Application Data
(63) Continuation of application No. PCT/US2012/059388, filed on Sep. 9, 2012.
(60) Provisional application No. 61/550,842, filed on Oct. 24, 2011.

(51) Int. Cl. G03F 7/40; G03F 7/22

(52) U.S. Cl. CPC G03F 7/40; G03F 7/22
USPC 430/323; 430/322; 430/324; 430/325

(57) ABSTRACT

Embodiments of the present invention are directed to techniques for obtaining patterns of features. One set of techniques uses multiple-pass rolling mask lithography to obtain the desired feature pattern. Another technique uses a combination of rolling mask lithography and a self-aligned plasmonic mask lithography to obtain a desired feature pitch.

### FIELD OF THE INVENTION

Embodiments of the invention relate to photolithography and more particularly to printing a pattern of features characterized by a given pitch and feature size.

### BACKGROUND

This section describes background subject matter related to the disclosed embodiments of the present invention. There is no intention, either express or implied, that the background art discussed in this section legally constitutes prior art.

Nanostructuring is necessary for many present applications and industries and for new technologies and future advanced products, such as wire grid polarizers for flat panel displays. Nanostructured substrates may be fabricated using techniques such as e-beam direct writing, deep UV lithography, nanosphere lithography, nanoimprint lithography, near-field phase shift lithography, and plasmonic lithography, for example.

A number of applications, such as wire-grid polarizers (among others) require a large-scale pattern of parallel spaced metal lines characterized by large pattern size, but small pitch, small linewidth, and small thickness, e.g., greater than about 1 centimeter (e.g., several tens of centimeters) in size (length and/or width) less than about 100 nm pitch, less than about 50 nm linewidth and depth of about 100 nanometers. Large scale wire-grid polarizers are desirable for use in flat panel displays. There may also be applications that can benefit from large scale non-periodic arrays of metal features.

There are a number of different lithography techniques for obtaining metal patterns with the desired pitch, linewidth and line thickness. These techniques are based, e.g., on conventional photolithography methods that are commonly used in semiconductor device fabrication. Unfortunately, these techniques were developed for patterning of a semiconductor die and then repeating the pattern several times over a wafer. The wafer can be 300 millimeters in diameter. Unfortunately, the pattern is only continuous over an area of about 1 centimeter by 1 centimeter. Although the pattern could be repeated, it is difficult to get adjacent patterns to align closely enough that the polarizer works without producing distracting visual artifacts.

A method of nanopatterning large areas of rigid and flexible substrate materials based on near-field optical lithography is described in International Patent Application Publication WO2009094009 and U.S. Patent Application Publication US20090297989, both of which are incorporated herein by reference. In this technique, a rotatable mask is used to image a radiation-sensitive material. Typically the rotatable mask comprises a cylinder or cone. The nanopatterning technique makes use of near-field photolithography, where the mask used to pattern the substrate is in contact with the substrate. Near-field photolithography may make use of an elastomeric phase-shifting mask, or may employ surface plasmon technology, where a rotating cylinder surface comprises metal nano holes or nanoparticles. In one implementation such a mask is a near-field phase-shift mask. Near-field phase shift lithography involves exposure of a photoresist layer to ultraviolet (UV) light that passes through an elastomeric phase mask while the mask is in conformal contact with a photoresist. Bringing an elastomeric phase mask into contact with a thin layer of photoresist causes the photoresist to “wet” the surface of the contact surface of the mask. Passing UV light through the mask while it is in contact with the photoresist exposes the photoresist to the distribution of light intensity that develops at the surface of the mask. A phase mask is formed with a depth of relief that is designed to modulate the phase of the transmitted light by π radians. As a result of the phase modulation, a local null in the intensity appears at step edges in the relief pattern formed on the mask. When a positive photoresist is used, exposure through such a mask, followed by development, yields a line of photoresist with a width equal to the characteristic width of the null in intensity. For 365 nm (Near UV) light in combination with a conventional photoresist, the width of the null in intensity is approximately 100 nm. A PDMS mask can be used to form a conformal, atomic scale contact with a layer of photoresist. This contact is established spontaneously upon contact, without applied pressure. Generalized adhesion forces guide this process and provide a simple and convenient method of aligning the mask in angle and position in the direction normal to the photoresist surface, to establish perfect contact. There is no physical gap with respect to the photoresist. PDMS is transparent to UV light with wavelengths greater than 300 nm. Passing light from a mercury lamp (where the main spectral lines are at 355-365 nm) through the PDMS while it is in conformal contact with a layer of photoresist exposes the photoresist to the intensity distribution that forms at the mask.

The aforementioned technique can be used to pattern very large areas with the desired linewidth using a phase mask. Unfortunately, it is difficult to laminate or deposit metal onto a mask made of elastomeric materials such as polydimethyl siloxane (PDMS).

It is within this context that embodiments of the present invention arise.

### SUMMARY

A pattern of features characterized by a desired pitch and feature size may be printed according to a first method. A photoresist on a substrate is contacted with a surface of a cylindrical mask having a pattern formed on the surface. The pattern may be periodic or non-periodic. Radiation is transmitted from inside the cylindrical mask through the pattern formed on the surface to the surface. The cylindrical mask rotates while the substrate translates and contact is maintained between the mask and the photoresist in two or more passes of the substrate past the cylindrical mask to expose the photoresist to two or more corresponding patterns of features. Each pattern of features is characterized by the given pitch and feature size, An offset between the two or more patterns results in a combination of the two or more patterns of features that is characterized by a desired pitch that is less than the given pitch.

According to a second method, a first photoresist layer on a substrate may be contacted with a surface of a cylindrical mask having a pattern of features formed on the surface, transmitting radiation from inside the cylindrical mask through the pattern formed on the surface of the cylindrical mask to the first photoresist layer. The cylindrical mask rotates while translating the substrate and maintaining contact between the mask and the first photoresist layer to expose the first photoresist layer to a corresponding first pattern of features. The first pattern of features is characterized by the given pitch and feature size. The first photoresist layer is developed to expose portions of the substrate to openings in the photoresist corresponding to the pattern of features; Metal is then deposited through the openings onto the substrate, thereby forming a corresponding first pattern of metal features on the substrate. The first photoresist layer is then removed; a spacer layer is formed over the substrate and the first pattern of metal features; and a second photoresist layer is formed over the spacer layer. The metal features are illuminated through the substrate with radiation characterized by a wavelength and intensity configured to generate a pattern of surface plasmons within the metal features. The pattern of plasmons results in portions of the second photoresist layer between the metal features being soluble. The second photoresist is developed to form openings at the soluble portions thereby forming a second pattern of features that are located in spaces between features in the first pattern of metal features. Portions of the spacer layer are etched through the openings in the second photoresist layer to expose corresponding portions of the substrate. Metal is deposited through the openings in the second photoresist layer to form a second pattern of metal features.

### BRIEF DESCRIPTION OF THE DRAWINGS

FIGS. 1A-1B are a sequence of schematic diagrams illustrating printing a pattern using rolling mask nanolithography in accordance with an embodiment of the present invention.

FIG. 2 is a schematic diagram illustrating printing a pattern using rolling mask nanolithography in accordance with an alternative embodiment of the present invention.

FIGS. 3A-3B are a sequence of schematic diagrams illustrating printing a pattern using rolling mask nanolithography in accordance with yet another embodiment of the present invention.

FIG. 4 is a schematic diagram illustrating printing a pattern using rolling mask lithography at two different angles in accordance with an alternative embodiment of the present invention.

FIGS. 5A-5H are a sequence of schematic diagrams illustrating printing a pattern using rolling mask nanolithography in accordance with still another embodiment of the present invention.

FIGS. 6A-6I are a sequence of schematic diagrams illustrating printing a pattern using rolling mask nanolithography in conjunction with a self-aligned process in accordance with another alternative embodiment of the present invention

### DETAILED DESCRIPTION

As a preface to the detailed description, it should be noted that, as used in this specification and the appended claims, the singular forms “a”, “an”, and “the” include plural referents, unless the context clearly dictates otherwise.

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” “above”, “below”, etc., is used with reference to the orientation of the figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

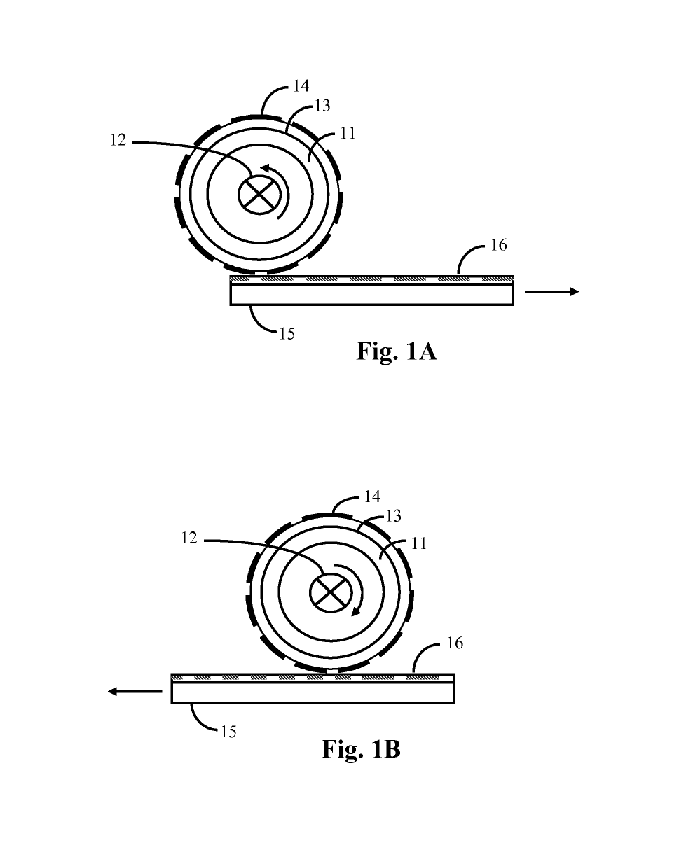

Embodiments of the present invention may be used in conjunction with a type of lithography known as “rolling mask” nanolithography. An example of a “rolling mask” near-field nanolithography system is described in International Patent Application Publication Number WO2009094009, which is incorporated herein by reference. An example of such a system is shown in FIG. 1. The “rolling mask” may be in the form of a glass (quartz) frame in the shape of hollow cylinder 11, which contains a light source 12. An elastomeric film 13 laminated on the outer surface of the cylinder 11 may have a nanopattern 14 fabricated in accordance with the desired pattern. The nanopattern 14 can be designed to implement phase-shift exposure, and in such case is fabricated as an array of nanogrooves, posts or columns, or may contain features of arbitrary shape.

By way of example, and not by way of limitation, the nanopattern 14 on the cylinder 11 may have features in the form of parallel lines having a linewidth of about 50 nanometers and a pitch of about 200 nanometers or greater. In general, the linewidth may be in a rage from about 1 nanometer to about 500 nanometers and pitch may range from about 10 nanometers to about 10 microns. Although examples are described herein in which the nanopattern 14 is in the form of regularly parallel lines, the nanopattern may alternatively be a regularly repeating two-dimensional pattern, having regularly-spaced and arbitrarily-shaped spots. Furthermore, the pattern features (lines or arbitrary shapes) may be irregularly spaced.

The nanopattern 14 on the cylinder 11 is brought into a contact with a photosensitive material 16, such as a photoresist that is coated on a substrate 15. The photosensitive material 16 is exposed to radiation from the light source 12 and the pattern 14 on the cylinder 11 is transferred to the photosensitive material 16 at the place where the nanopattern contacts the photosensitive material. The substrate 15 is translated as the cylinder rotates such that the nanopattern 14 remains in contact with the photosensitive material. Depending on the nature of the photosensitive material, portions of the pattern that are exposed to radiation may react with the radiation so that they become removable or non-removable.

By way of example, if the photosensitive material is a type of photoresist known as a positive resist, the portion of the material that is exposed to light becomes soluble to a developer and the portion of the material that is unexposed remains insoluble to the developer. By way of counterexample, if the photosensitive material is a type of photoresist known as a negative resist, the portion of the material that is exposed to light becomes insoluble to a developer and the unexposed portion of the material is dissolved by the photoresist.

In certain embodiments of the present invention, the photosensitive material 16 is exposed by passing the substrate past the cylinder 11 two or more times. For sufficiently small values of the pitch and linewidth, the linear pattern of exposure resulting from one pass is unlikely to line up with each other. As a result, lines from one pass are likely to end up between lines of a previous pass. By careful choice of the pitch, linewidth, and number of passes it is possible to end up with a pattern of lines in the photosensitive material 16 that has a pitch smaller than the pitch of the lines in the pattern 14 on the cylinder 11.

It is noted that in the example illustrated in FIG. 1A-FIG. 1B the substrate 15 translates in a first direction (e.g., to the right in this example) and the cylindrical mask 11 rotates in a corresponding first sense (e.g., counterclockwise in this example) and in a second pass the substrate 15 translates in a second direction (e.g., to the left in this example) opposite the first direction and the cylindrical mask 11 rotates in a second sense opposite the first sense (e.g., clockwise in this example). In the first pass, the lines (or spots) in the pattern 14 are transferred to the photosensitive material as a result of exposure of the photosensitive material to radiation from the source 12 through the pattern 14. In the second pass, previously unexposed portions of the photosensitive material 16 located between neighboring exposed lines or spots are exposed. The linewidth (or spot size) remains more or less the same for both passes, but the resulting pattern in the photosensitive material has a smaller pitch due to the exposure of previously unexposed portions between neighboring exposed portions.

It is noted that the foregoing is only one example and embodiments of the present invention are not limited to the implementation depicted in FIGS. 1A-1B. Alternatively, the substrate 15 may pass the rotating cylindrical mask 11 two times in the same direction (e.g., two times to the right) with the cylinder 11 rotating the same way (e.g., counterclockwise) for each pass.

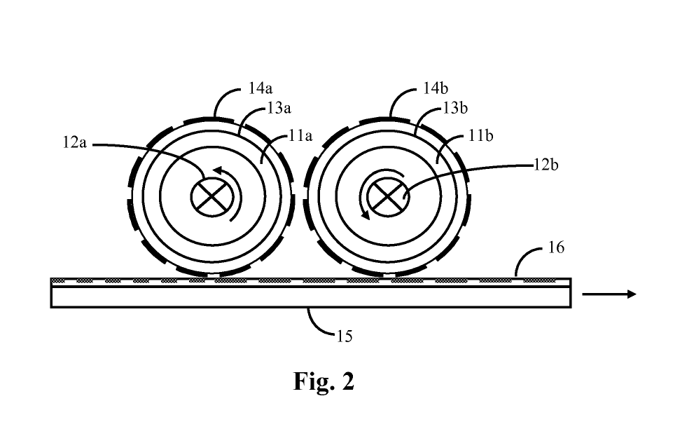

Other variations are possible. For example, as shown in FIG. 2, two passes may be accomplished using two rotating cylindrical masks 11a, 11b with corresponding light sources 12a, 12b, elastomeric films 13a, 13b, and patterns 14a, 14b. The two rotating cylindrical masks may be arranged in tandem and passing the substrate, e.g., on a conveyor belt such that the substrate 15 passes past one mask 11a and then the other 11b. The patterns 14a, 14b on the masks 11a, 11b may have parallel lines characterized by the same pitch and linewidth of the lines in patterns 14a, 14b or the two patterns may have slightly different pitch and/or linewidth.

Although the foregoing example describes an embodiment in which periodic patterns of regularly spaced lines are used, embodiments of the invention are not limited to such implementations. Alternatively, non-periodic patterns may be used. It is noted that non-periodic patterns could be designed to avoid a potential problem with periodic arrays. With periodic structures and a double exposure via a “second roll” can produce areas where lines are nicely separated and areas where lines overlap considerably. A non-periodic arrangement (e.g., a chirped grating or a quasi-random sequence such as a Fibonacci sequence) could produce a more even spread of the regions where exposed lines lie on top of each other. Non-periodic grating structures and scattering nanoparticle arrays may also be preferable for solar cell applications.

Furthermore, embodiments of the present invention are flexible with respect to the feature size in the patterns. For example, it may be desirable to print patterns with different linewidths in different passes. Specifically, wide lines may be printed in a first “roll”/exposure and narrow lines may be printed in a second exposure.

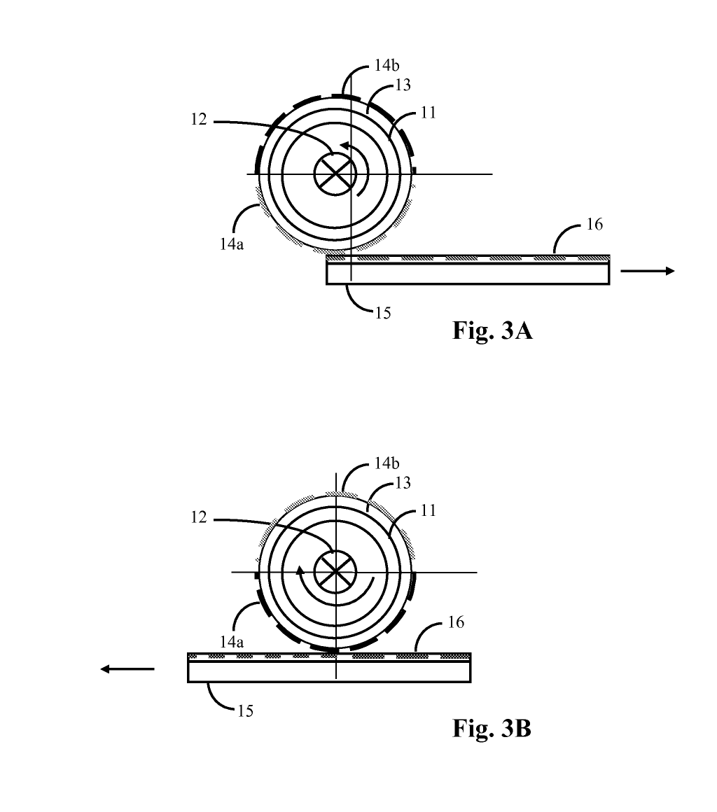

In another embodiment, illustrated in FIGS. 3A-3B, a single rotating cylindrical mask 14 may have two different patterns 14a, 14b on different portions. The patterns may be characterized by different pitch, linewidth (or spot size), or different shaped spots with the same pitch or different pitches. In a first pass, the photosensitive material 16 may be exposed to the first pattern 14a, as shown in FIG. 3A and in a second pass, the photosensitive material 16 may be exposed to the second pattern 14b.

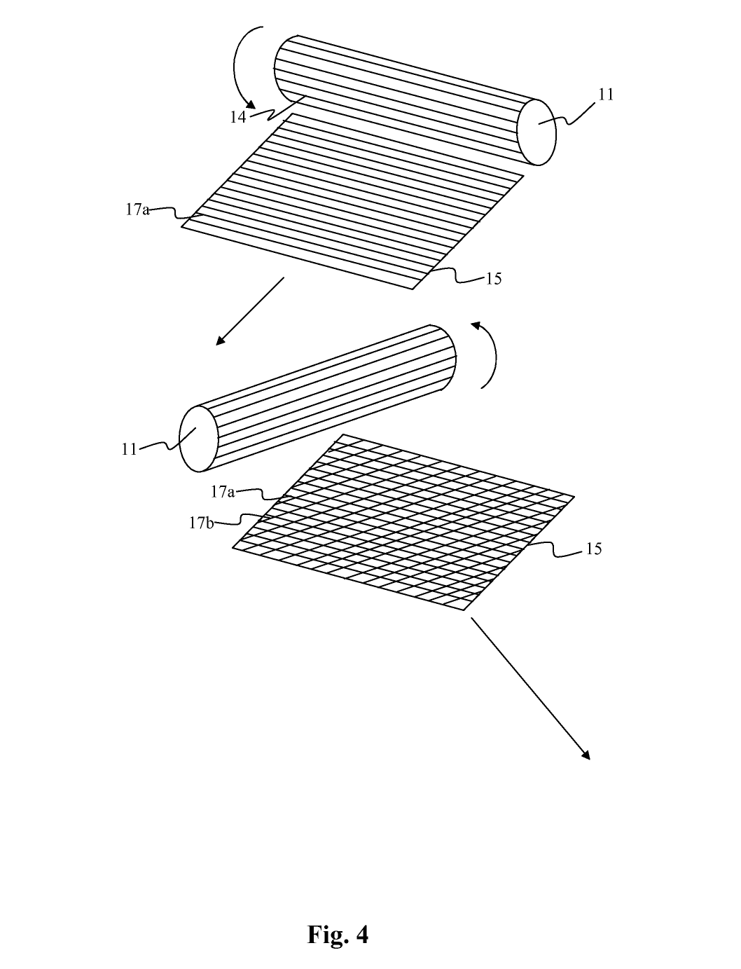

In certain embodiments, the two or more passes may be done at slightly different angles. For example, as shown in FIG. 4 the two or more passes include a first pass of the substrate 15 at a first angle relative to an axis of the cylindrical mask 11 and a second pass at a different second angle relative to the axis of the cylindrical mask. In the example illustrated in FIG. 4, in the first pass, the substrate 15 moves perpendicular to the axis of the cylindrical mask 11 and at an oblique angle to the axis in the second pass. It is noted that substrate may pass the same cylindrical mask in both passes or the first and second passes may be done using different masks.

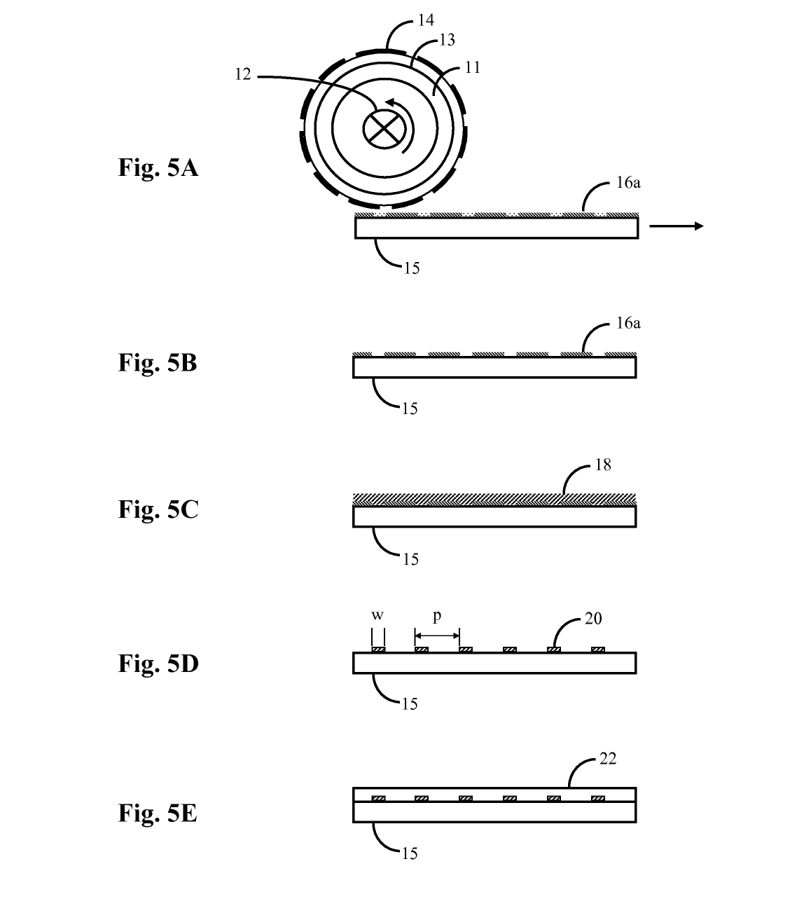

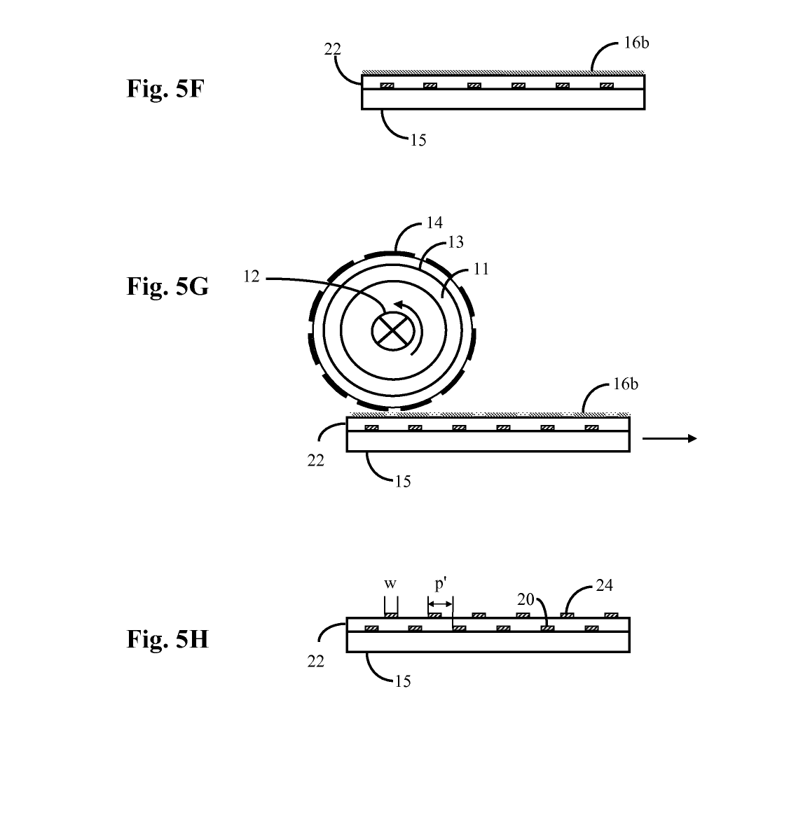

It is noted that in certain embodiments of the invention, the two or more passes of the substrate past the cylindrical mask may expose two different layers of photosensitive material to form two overlapping patterns. For example, FIGS. 5A-5H illustrate an example in which a first pattern is formed on a first photoresist layer and a second pattern is formed in a second photoresist layer. Specifically, as shown in FIG. 5A, a first photoresist layer 16a on the substrate 15 may be exposed to radiation from a source 12 through a pattern 14 in a cylindrical mask 11 as the mask rotates and the substrate translates. The first photoresist layer 16a may then be developed as shown in FIG. 5B to form a first pattern of openings in the first photoresist layer 16a that exposes portions of the substrate 15. Material 18 may then be deposited material onto the substrate 15 through the openings to form a pattern of material corresponding to the openings as shown in FIG. 5C. By way of example, and not by way of limitation, the material 18 may be a metal, such as Aluminum, Gold, Copper, to name just a few examples, which may be deposited, e.g., by physical vapor deposition (PVD), chemical vapor deposition (CVD), atomic layer deposition (ALD, or from liquid phase in the form of metal particles suspensions. This material may also be an insulator such as glass or Aluminum Oxide, an organic, such as a polymer or small molecule, or a semiconductor, such as Silicon, Germanium, or Gallium Arsenide. Excess material 18 and the first photoresist layer 16a may be removed leaving a pattern of material features 20 characterized by a feature size w and pitch p as shown in FIG. 5D.

A transparent spacer layer 22 may then be formed on the substrate 15 and the pattern of material features 20 as shown in FIG. 5E. By way of example, and not by way of limitation, the spacer layer may be formed using a spin-on glass (SOG) deposition from a liquid precursor or by physical (PVD) or chemical vapor deposition (CVD) or atomic layer deposition (ALD) of a suitable material, such as a silicon oxide. The spacer layer 22 can therefore be made quite thin. A second photoresist layer 16b may then be deposited on the transparent spacer layer 22 as shown in FIG. 5F. The second photo resist layer may be exposed to a second pattern, e.g., by passing the substrate past the rotating cylindrical mask 11 a second time and exposing the second photoresist 16b to radiation from the source 12 during the second pass as shown in FIG. 5G. Alternatively, the second pass may be done by passing the substrate past a second cylindrical mask have the same or a different pattern formed on its surface.

After the second photoresist layer 16b has been exposed, it may be developed to form a pattern of openings at locations between features 20 in the material pattern on the substrate 15. The openings in the second photoresist layer 16b expose underlying portions of the spacer layer 22. Additional material 18 may be deposited through these openings over the spacer layer 22 and the second photoresist layer 16b. Excess additional material and the second photoresist layer 16b may be removed leaving behind a second pattern of material features 24. The combination of the two patterns of features 20, 24 provides an overall pattern characterized by a smaller pitch p′.

An advantage of the technique illustrated in FIGS. 5A-5H is that it allows the second pattern of features 24 to be removed without disturbing the first pattern of features 20. This facilitates multiple tries to get proper alignment between the first pattern of features 20 and the second pattern of features 24.

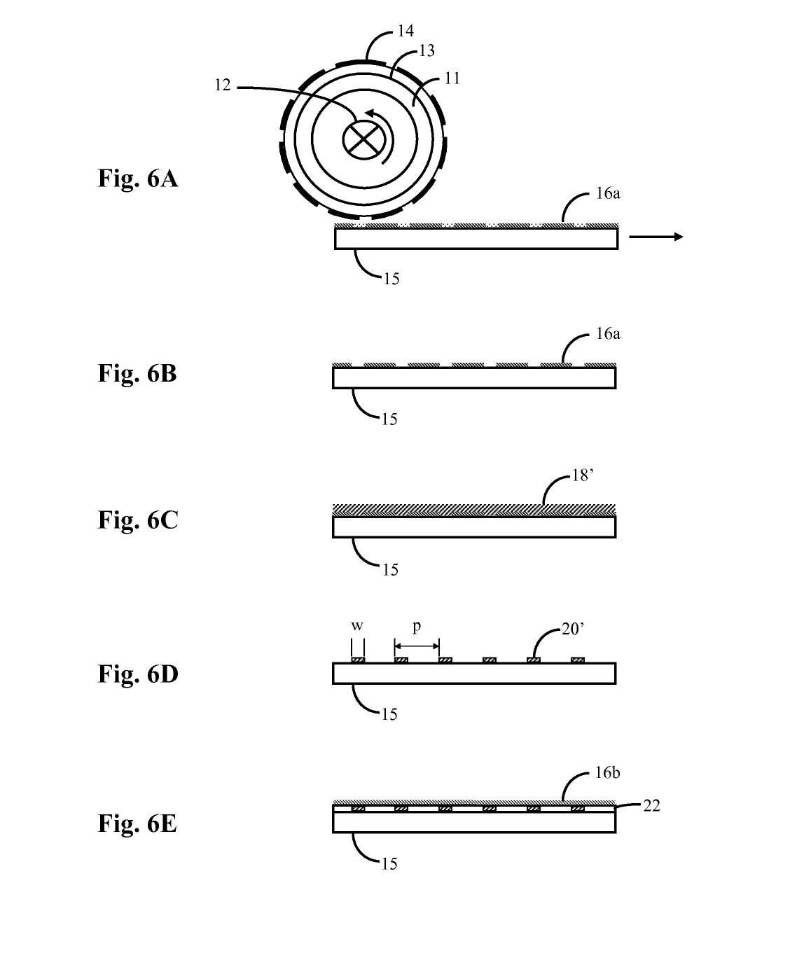

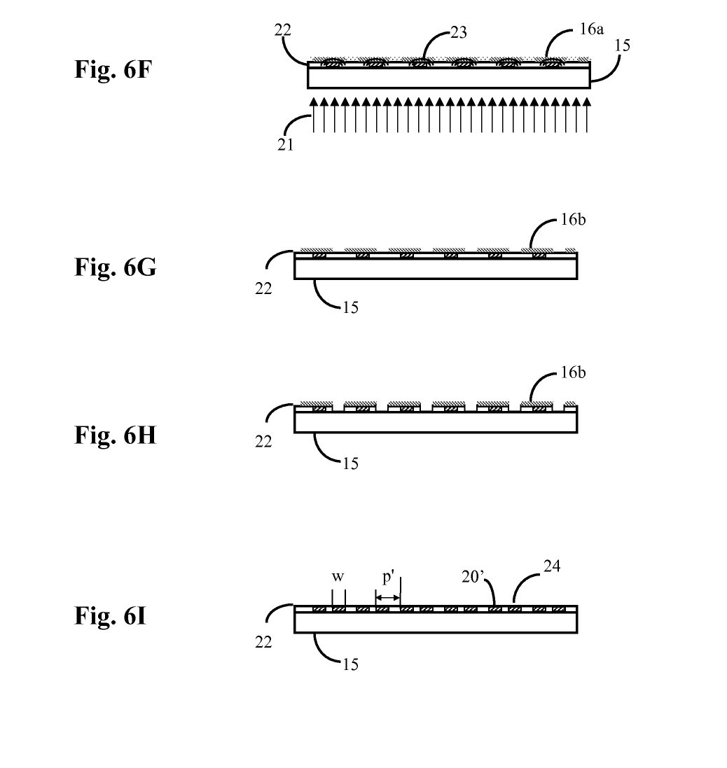

Embodiments of the present invention also include techniques for forming a pattern of features characterized by a given pitch and feature size using a single pass in conjunction with plasmonic lithography. For example, FIGS. 6A-6I illustrate an example of such a technique.

The technique begins in much the same fashion as illustrated in FIGS. 5A-5F. Specifically, as shown in FIG. 6A, a first photoresist layer 16a on the substrate 15 may be exposed to radiation from a source 12 through a pattern 14 in a cylindrical mask 11 as the mask rotates and the substrate translates. The first photoresist layer 16a may then be developed as shown in FIG. 6B to form a first pattern of openings in the first photoresist layer 16a that exposes portions of the substrate 15. Metal 18′ may then be deposited material onto the substrate 15 through the openings to form a pattern of metal features 20′ corresponding to the openings as shown in FIG. 6C. By way of example, and not by way of limitation, the metal 18′ may be Aluminum, which may be deposited, e.g., by physical vapor deposition (PVD). Excess metal 18′ may be removed, e.g., by chemical mechanical polishing (CMP) and the first photoresist layer 16a may also be removed by conventional techniques leaving behind a pattern of metal features 20′ characterized by a feature size w and pitch p as shown in FIG. 6D.

As shown in FIG. 6E, a transparent spacer layer 22 may then be formed on the substrate 15 and the pattern of metal features 20′ and a second photoresist layer 16b may be formed on the spacer layer. The spacer layer 22 can therefore be made quite thin. By way of example, and not by way of limitation, the spacer layer may be formed using a spin-on glass (SOG) or by atomic layer deposition (ALD) of a suitable material, such as a silicon oxide.

The metal features 20′ are then illuminated through the substrate 15 with radiation 21 radiation. The material of the substrate 15 is also selected to be transparent to the radiation 21, which is characterized by a wavelength and intensity configured to generate a pattern of plasmons within the metal features 20′. The pattern of plasmons in the metal produces a corresponding pattern of radiation 23 that interacts with second photoresist layer 22. The pattern of radiation produced by the plasmons results in portions of the second photo resist layer between the metal features being soluble. Exposure of the resist to the plasmons may make the resist either soluble or insoluble depending on the type of photoresist. The illumination wavelength of the radiation 21 may be in the UV or deep UV as with regular photolithography. The size of the features that can be made by this technique may be between 25 nm and a few 100 nm. The pitch of features that can be made may be between 50 nm and a few 100 nanometers. The metal features 20 made during the initial roll/exposure may be on the order of 100 nm to a few 100 nm.

The second photoresist 22 may then be developed as shown in FIG. 6G to form openings at the soluble portions thereby forming a second self-aligned pattern of features that are located in spaces between features in the metal features 20. Portions of the spacer layer may then be etched through the openings in the second photo resist layer 22 to expose corresponding portions of the substrate 15 as shown in FIG. 6H.

Additional metal may then be deposited through the openings in the second photoresist layer to form a second pattern of metal features 20″ that overlaps with the features 20′ of the first pattern. After removal of excess metal and the second photoresist layer, the resulting combination of the two sets of features 20′, 20″ provides an overall pattern having a smaller pitch p′ than the initial pitch p in the first pattern of metal features 20 as shown in FIG. 6I.

While the above is a complete description of the preferred embodiments of the present invention, it is possible to use various alternatives, modifications, and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A” or “An” refers to a quantity of one or more of the item following the article, except where expressly stated otherwise. The appended claims are not to be interpreted as including means-plus-function limitations, unless such a limitation is explicitly recited in a given claim using the phrase “means for”. Any element in a claim that does not explicitly state “means for” performing a specified function, is not to be interpreted as a “means” or “step” clause as specified in 35 USC §112, ¶6.

What is claimed is:

1. A method for printing a pattern of features, the method comprising:
contacting a photoresist on a substrate with a surface of a cylindrical mask having a pattern formed on the surface, transmitting radiation from inside the cylindrical mask through the pattern formed on the surface to the surface;
rotating the cylindrical mask, while translating the substrate and maintaining contact between the mask and the photoresist in two or more passes of the substrate past the cylindrical mask to expose the photoresist to two or more corresponding patterns of features.

2. The method of claim 1, further comprising developing the photoresist.

3. The method of claim 2, wherein a material layer is formed between the substrate and the photoresist; the method further comprising etching the material layer through a pattern in the developed photoresist to produce a pattern having a spatial period less than that of a spatial period of a pattern on the cylindrical mask.

4. The method of claim 3, further comprising etching the substrate through pattern in the material layer.

5. The method of claim 1, wherein the mask is a phase mask.

6. The method of claim 1, wherein the two or more passes include a first pass with the substrate translating in a first direction and the cylindrical mask rotating in a corresponding first sense a second pass with the substrate translating in a second direction opposite the first direction and the cylindrical mask rotating in a second sense opposite the first sense.

7. The method of claim 1, wherein the two or more passes include a first pass with the substrate translating in a first direction and the cylindrical mask rotating in a corresponding first sense a second pass with the substrate translating in the first direction and the cylindrical mask rotating in the first sense.

8. The method of claim 1, wherein the two or more passes include a first pass past a first cylindrical mask with the substrate translating and the first cylindrical mask rotating in a corresponding sense and a second pass past a second cylindrical mask with the substrate translating and the second cylindrical mask rotating in a corresponding sense.

9. The method of claim 9, wherein the first and second cylindrical masks are arranged in tandem with the substrate passing both the first and second cylindrical masks in the same direction with both cylindrical masks rotating in the same corresponding sense.

10. The method of claim 1 wherein the two or more passes include a first pass of the substrate at a first angle relative to an axis of the cylindrical mask and a second pass at a second angle relative to the axis of the cylindrical mask, wherein the first and second angles are different.

11. The method of claim 1 wherein the two or more passes include a first pass of the substrate at a first angle relative to an axis of the cylindrical mask and a second pass at a second angle relative to the axis of a different cylindrical mask, wherein the first and second angles are different.

12. The method of claim 1, wherein the two or more passes includes first and second passes, the method further comprising, developing the photoresist after the first pass to form openings that expose portions of the substrate; depositing material on the substrate through openings to form a pattern of material corresponding to the openings; forming a transparent spacer layer on the substrate and the pattern of material; depositing a second photoresist on the transparent spacer layer and exposing the second photoresist during the second pass.

13. The method of claim 1, wherein each pattern of features is characterized by a corresponding pitch and feature size, wherein an offset between the two or more patterns results in a combination of the two or more patterns of features that is characterized by a pitch that is less than the pitch for any of the two or more corresponding patterns of features.

14. The method of claim 1, wherein the two or more patterns include features of different feature sizes.

15. The method of claim 14, wherein the two or more passes include a first pass with a first feature and a second pass with a second feature pattern, wherein the second feature pattern is characterized by a smaller feature size than the first pattern.

16. The method of claim 1, wherein the two or more corresponding patterns of features are periodic patterns having regularly-spaced features.

17. The method of claim 1, wherein the two or more corresponding patterns of features are non-periodic patterns having irregularly-spaced features.

18. The method of claim 17, wherein at least one of the two or more corresponding patterns includes a chirped grating or quasi-random sequence of features.

19. A method for printing a pattern of features characterized by a given pitch and feature size, the method comprising:
contacting a first photoresist layer on a substrate with a surface of a cylindrical mask having a pattern of features formed on the surface, transmitting radiation from inside the cylindrical mask through the pattern formed on the surface of the cylindrical mask to the first photoresist layer;
rotating the cylindrical mask, while translating the substrate and maintaining contact between the mask and the first photoresist layer to expose the first photoresist layer to a corresponding first pattern of features, wherein the first pattern of features is characterized by the given pitch and feature size;
developing the first photoresist layer to expose portions of the substrate to openings in the photoresist corresponding to the pattern of features;
depositing metal through the openings onto the substrate, thereby forming a corresponding first pattern of metal features on the substrate;
removing the first photoresist layer;
forming a spacer layer over the substrate and the first pattern of metal features;
forming a second photoresist layer over the spacer layer;
illuminating the metal features through the substrate with radiation characterized by a wavelength and intensity configured to generate a pattern of plasmons within the metal features, wherein the pattern of plasmons results in portions of the second photo resist layer between the metal features being soluble;
developing the second photoresist to form openings at the soluble portions thereby forming a second pattern of features, wherein features in the second pattern are located in spaces between features in the first pattern of metal features;
etching portions of the spacer layer through the openings in the second photo resist layer to expose corresponding portions of the substrate; and
depositing metal through the openings in the second photoresist layer to form a second pattern of metal features.
